(19) United States
(12) Patent Application Publication
(10) Pub. No.: US 2011/0200202 A1
(43) Pub. Date: Aug. 18, 2011

(54) Special novelty effects apparatus for bicycles

(76) Inventor: George Ray Flanigan, Mt. Prospect, IL (US)

(21) Appl. No.: 12/931,960

(22) Filed: Feb. 15, 2011

Related U.S. Application Data
(60) Provisional application No. 61/338,375, filed on Feb. 18, 2010.

(51) Int. Cl. H03G 3/00

(52) U.S. Cl. 381/61

(57) ABSTRACT

Special novelty effects apparatus are provided for inclusion on bicycles providing a synthesizer circuit device having a microprocessor circuit element and a memory chip element or flash drive element for receiving instructions for novelty sound and lighting effects that simulate atypical sounds and lighting as would be expected to emanate from a bicycle, such as sound of a motorcycle throttling in takeoff with simulated tailpipe emissions though lighting effects, or sounds of a truck or airplane, all for the recreational and entertainment application to a rider of a bicycle.

### BACKGROUND OF THE INVENTION

1. Field of the Invention

The present invention relates generally to the application of special novelty effects of sound and lighting for bicycles and more particularly to providing novelty sound and lighting effects to a bicycle to produce selected ones of sounds such as music, air horn or air brakes of a semi-trailer truck, sound of a motorcycle engine, an aircraft during takeoff, and selected associated lighting by means of front and rear lights that are associated with the sound of a motorcycle engine or aircraft takeoff and/or turn signals, the special novelty effects being created by a standard manufacture synthesizer circuit with memory chip and microprocessor capacity, and switch means to select the desired simulated sounds and/or lighting sequences or tracks.

2. Background of the Invention

The bicycle is and remains a favor means of fun and transportation for the general public, younger and older alike, and a wide variety of types, shapes and deployments of attachments and accessories are available in the public domain, most of which relate or pertain to enhancement of the particular utility intended for the bicycle user or rider, such as lighting for front and rear lights, baskets, saddlebags, double seats, carriages and windshields. However, for younger riders the present invention presents special novelty effects apparatus of sound and lighting to assimilate the sounds of adult transportation vehicles or music by use of a synthesizer circuit having a microprocessor and memory chip into which can be inserted a flash drive media with desired sounds and lighting activations, for example, providing the sounds of a motorcycle throttling or revving for takeoff or moving away with tailpipes lit as though gaseous emissions were emitting from tailpipe, or the sound of an aircraft taking off, or the sound of an air-horn or air-brakes or engine noise of a semi-trailer truck, or music of a desired sound track.

### DESCRIPTION OF THE PRIOR ART

Although the inventor has researched the prior art to ascertain applicable prior art novelty apparatus for application to bicycles, the lack of applicable prior art particular to the special novelty effects area has encouraged the inventor to file this utility patent application. The present invention is the subject of a provisional patent application made by the inventor under Ser. No. 61/209,498, filed Mar. 9, 2009, and a provisional continuation patent application identified as Ser. No. 61/338,375 filed Feb. 18, 2010, entitled “Special Lighting and Sound Effects for a Bicycle”.

The field of application of the present invention and its special novelty effects apparatus is applicable to any moving vehicle to which attachment is made, such as a tricycle, wagon, skate board, scooter, or bicycle, but is deemed best employed on a bicycle. There is provided simulation gas tank plate means to be attached to the frame of the bicycle in a forward position of the frame to simulate a gas tank of a motorcycle or gas driven vehicle. There is provided simulation engine plate means to be attached to the central portion of the bicycle frame generally disposed under the seat of the bicycle to simulate an engine of a motorcycle or gas driven vehicle. A standard manufacture version of synthesizer circuit means having a microprocessor circuit and memory chip or flash drive circuit is provided and desirably housed interiorly to or mounted on the simulated gas tank plate means. Power means is provided to energize the synthesizer circuit means. Primary switching means having multiple switch settings, each setting active to select a desired assimilated sound or lighting effect is provided and wired to the synthesizer circuit means to select a desired identified novelty effect of sound or lighting or both. Simulated tailpipe plate means are provided to extend rearward along the rear wheel of the bicycle, to provide simulated tailpipe(s). Front speaker means are provided for producing the sounds of an air-horn or air-brakes or motor noises. Rear mounted speaker means are mounted interiorly to or attached to the tailpipe means to provide sound effects or sound tracks as selected from the synthesizer circuit means. Lighting means are mounted to the rear end or free end portion of the tailpipe means to light up for simulation of gaseous emissions as would emit from motorcycle tailpipes responsive to take-off throttling action. Potentiometer means are preferably mounted to a selected free end portion of the bicycle handle bars, left or right, and provide pivotable handle means to simulate or replicate the feel and look of pivoting motorcycle throttle device. The potentiometer can be connected to the tailpipe speakers to provide that with a desired pivot position, and when the synthesizer circuit is correspondingly selected by the primary switch means, the sounds of a motorcycle engine throttling to increased rpm are emitted from the tailpipe speaker means. Simultaneously, lighting means provided on the free end portion of the tailpipe plate means lights to simulate gaseous emissions of a moving motorcycle on take-off. Turn signal lighting means are provided having push button controls mounted on the handle bars or adjacently thereto. The selection of a left or right hand turn push button control of the turn signal lighting means provides lighting signals for a left directional or right directional turn, respectively. Front mounted head light means is provided to simulate the front head light of a motorcycle and when switched to the “On” position, all lighting is activated on the bicycle including turn signal activation to enable activations of left directional or right directional push buttons and corresponding left and right real lighting provided on the simulated tailpipes.

The prior art is not known by the inventor to provide such special novelty effects apparatus as set forth and described by the present invention nor any combination thereof, as shown and disclosed by detailed description and drawings of the present invention.

### SUMMARY OF THE INVENTION

The present invention provides special novelty effects apparatus for bicycle application and comprised in combination and including synthesizer circuit means with microprocessor and memory chip or flash drive means included therein to accept a designed memory chip or flash drive card insert, switching means to select one of multiple tracks provided by the synthesizer circuit means, speaker means including frontal and rearward directed speaker devices, lighting means including frontal and rearward directed lighting apparatus, power means to provide power to the synthesizer circuit means, potentiometer means to provide a simulated hand throttle on the handle bar area of the bicycle, effective when rotated to activate sounds to the rearward directed speaker device, when the synthesizer is appropriately switched by the switching means to provide the desired sound effects, such as throttling sound of a motorcycle, with corresponding lighting effects of the rearward directed lighting devices to provide the desired lighting effects, such as simulated emissions from a motorcycle tailpipe.

Another selection of the synthesizer circuit means may provide sounds from the frontal directed speaker device of air-horn or air-brakes or engine noises of a truck, or music from a selected sound track, or the sounds of an aircraft on take-off, in accordance with the programming of sounds and lighting effects of the synthesizer circuit means. Left and right hand directional turn signals with push-button controls are provided. All of the apparatus described and comprising a part of the present invention may be mounted in various manners and positions to the frame or parts of a bicycle or other movable device as used in recreational settings. The mounting techniques are of standard methods and do not comprise the novelty of the present invention and are intended to be within the scope and content of the present detailed description.

It is an object of the present invention to provide synthesized novelty effects apparatus to be mounted to or on a bicycle to provide such selected sounds as the take-off throttling of a motorcycle, take-off sounds of an aircraft, sounds of an air-horn, airbrake or engine noises of a truck, music from selected music tracks, and related lighting effects to enhance the simulations of such sounds.

It is an object of the present invention to provide such novelty sound and lighting effects through the use and application of a state of the art synthesizer circuit with microprocessor circuit and memory chip circuit or flash drive circuit to be appropriately formatted by a corresponding memory chip insert device or flash drive insert device, or preprogrammed to have fixed sound and/or lighting effects when properly selected switch means are activated by the rider of the bicycle.

It is a further object of the invention to provide separate power means to energize the synthesizer circuit and related circuits including speaker devices and lighting devices.

It is still another object of the invention to provide simulated throttle device in the form of potentiometer means, to simulate the hand throttle of a motorcycle.

These and other objects and uses and applications of the present invention will become readily apparent or obvious from the review and consideration of the disclosure of the present invention contained in the following specification and drawings, and all such other or obvious objects and uses and application are intended to be covered in the scope and intent of the detailed description of the present invention.

### BRIEF DESCRIPTION OF THE DRAWINGS

FIG. 1 is a side perspective view of a customary state of the art wheeled bicycle, having mounted or provisioned thereon, the special novelty effects apparatus of the present invention; and

FIG. 2 is a frontal perspective view of the bicycle of FIG. 1 showing some of the apparatus of the present invention.

Similar reference characters shall denote corresponding parts, features, or elements of the present invention consistently throughout the attached drawings.

### DETAILED DESCRIPTION OF THE PREFERRED EMBODIMENT

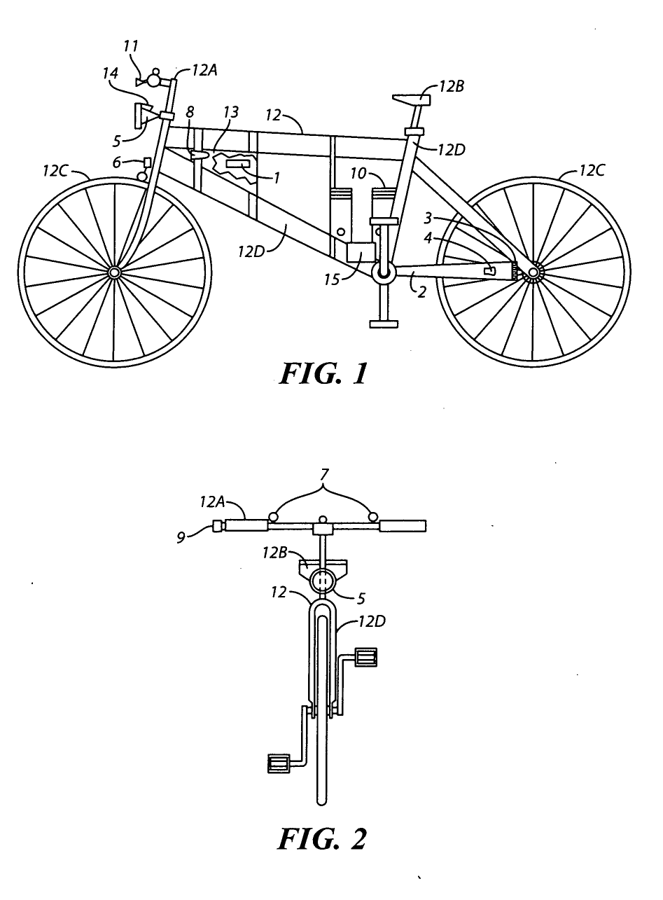

There is shown in FIG. 1 in accordance with the improved assembly of special novelty effects apparatus of the present invention, at reference number 1, a block reference to synthesizer circuit means 1 having as component parts or inclusions thereof, microprocessor circuit means and memory chip circuit means or alternatively, flash drive circuit means, suitable to insertion of selected memory chip or flash card devices, or alternatively, with the microprocessor circuit means memory chip circuit means of predetermined novelty sounds or lighting effects programmed therein. The synthesizer circuit means 1 with its associated microprocessor circuit means and memory chip circuit means, can be programmed or preprogrammed to provide such sound effects as a 1000 cc motorcycle, music, air-horn or air-brakes or engine noises of a semi-trailer truck, a 747 airplane taxing down the runway or taking off, all of which are novelty sounds emitting from a bicycle. Tailpipe replica plate means are provided at 2 as shown in FIG. 1, mounted to extend toward the rear direction as shaped in the bell shaped figure of a customary tailpipe, and may be mounted to one-side or both sides of a carrier frame. Tailpipe lighting devices or means 3 are mounted, FIG. 1, to the free end or rearmost section of the tailpipe means 2 and are activated to simulate tailpipe emissions during throttling or take-off movements. Rear mounted speaker devices or means 4 are mounted, FIG. 1, approximate to the free end or rearmost section of the tailpipe means 2 and are effective to emit sounds determined by the selected track of the synthesizer circuit means 1, such as the sound effects of the motorcycle, or other appropriate selected or predetermined tailpipe noises. For example, other tailpipe noises may be the beeping noise of a vehicle made to indicate or warn of backing movements. It would not be desirable to simulate or provide for emergency siren sounds of emergency vehicles, however.

Headlight or front lighting device or means 5 including side light signal devices are provided to be mounted to the front as shown in FIGS. 1 and 2 of the drawings, and may be provisioned to include one or more light bulbs to simulate the front lighting devices customarily associated with a motorcycle. When the headlight 5 is turned to the “On” position, the front and rear lights stay on unless interrupted by another overriding lighting function that is not inclusive of front lighting. Generator sensor device or means 6 are provided to be engaged to turn with movement of the bicycle 12. The bicycle 12 is illustrated in the drawings to be comprised of or include front handlebars 12A, seat 12B, front and rear wheels 12C and a frame 12D. The generator sensor means 6 is mounted to engage the front wheel and be moved thereby to generate the energy to power all the electrical components or to just generate a signal to control the operating frequency of the electrical components when the bicycle 12 is moving. When the bicycle 12 is moving, the generator sensor means 6 sets the frequency for the lights flashing and the simulated or replicate sound of a vehicle moving. Battery power means not shown in the drawings but included in the synthesizer circuit means 1 are required to be used with or without the use of the generator sensor 6.

Push button signal devices or means 7 provide left or right directional turn signals and are mounted to or proximate of the front handlebars 12A. When the appropriate left or right directional signal push button device 7 is pushed or activated, the same side lighting means 5 and 3 are activated to start flashing and the other side is deactivated so as not to flash, providing left or right directional turn signals, respectively. The flashing is preset for a determined time duration, such as 15 seconds, after which the frontal light device 5 and the rearward light device 3 will return to their preset positions or states. When the headlight device 5 is switched on, the tail light device 3 will operate off the turn signals.

Synthesizer switch device or means 8 is provided best shown in FIG. 1, and serves as a multi-positional selector switch for the multi-functions of the synthesizer circuit means 1, being mounted preferably proximate to the synthesizer circuit means 1 and having positions as follows: i) off position; ii) motorcycle simulations sounds and lighting effects position; iii) truck sound effects; iv) airplane sound effects; and v) other desired sound or lighting effects, including emergency parking lights or backing warning. The positions of the synthesizer switch means 8 are obviously varied to the desire of the multiplicity of simulations to be provided by the associated synthesizer circuit means 1.

There is shown in FIG. 2, potentiometer throttle device or means 9 provided on the selected free end portion of the handlebars 12A of the bicycle 12. The potentiometer means 9 is provided to be a pivotable throttle portion extending on the handlebars 12A to provide the simulation of a motorcycle throttle, which when turned or rotated in the same or similar manner as rotating the throttle of a motorcycle provides the sounds of a motorcycle engine through the circuit connections to the rear mounted speaker device(s) 4 mounted on or proximate to the simulated tailpipe plate means 2. Simultaneously, the tailpipe light means 3 flash to simulate burning of gas emitting from the tailpipe(s) 2. When the potentiometer device 9 is further positioned by rotation, as the bicycle moves forward, the rear speaker(s) 4 emit the sounds of a motorcycle moving forward, or in an alternative position of the switching device 8, emits the sounds of a truck or alternative position, the sounds of an airplane. In the music position, the speaker devices 4 or 11 as provided on the front of the bicycle 12 shown in FIG. 1, provide same associated sound effects, including air-horn for frontal movement. The potentiometer device 9 does not replace the front handle bars but is added to a selected end thereof, and is readily pivotable by hand strength of a child.

Engine simulated cover plate means is provided at 10 and attached to the frame 12D of the bicycle 12 by a variety of fasteners including screws or clips for ease of removal. The engine plate means 10 is not essential to the present invention but is intended to add to the image effects of simulation of a motorcycle. The front speaker device 11 is used primarily to provide music and sound of a truck air-horn or air-brakes. However, the front speaker device 11 can be made to emit any desired sound effect as is downloaded into the memory of the synthesizer circuit device 1.

Gas tank simulated cover plate means is provided at 13 of FIG. 1, and serves as the enclosure or mounting plate for the synthesizer circuit device 1 and the synthesizer switch device 8 and like the engine plate means 10, plate means 13 can be attached by a variety of fasteners including screws or clips for ease of removal. The cover platen means 13 is provided with a decal image of a gasoline tank to simulate the gas tank of a motorcycle. Another switch means 14 is provided on and operative to switch on or off the headlight device 5 as shown in FIG. 1. When the switch 14 is in the on position, all lights front and back remain on, except when the left or right directional turn signals 7 are pushed. Thereupon, the opposite side tail light 3 is turned off and the same side tail light 3 flashes for a predetermined time period such as the 15 seconds previously stated, after which the lights 5 and 3 return to the on position. A battery device 15 in FIG. 1 provides power supply required for the operations of circuitry including the synthesizer circuit means 1 and its associated microprocessor and memory circuit or flash drive.

In summary, the present invention provides special novelty effects apparatus for a wheeled device such as a bicycle 12, comprising in combination, synthesizer circuit means 1 including microprocessor circuit means and memory circuit means for providing predetermined programs for different sound effects for simulation of selected sounds atypical to the wheeled device 12 on which the synthesizer circuit means is mounted; synthesizer switch means 8 including multiple switch settings, each one of the switch settings responsive to select from the synthesizer circuit means 1 a different predetermined program of sound effects; tailpipe cover plate means 2 including tailpipe speaker device 4 responsive to a selected one of the synthesizer circuit means 1 predetermined programs to provide predetermined sound effect atypical to the sound of the wheeled device 12 on which mounted; and potentiometer throttle means 9 pivotable to a predetermined throttle position to activate a corresponding throttle sound effect provided by the synthesizer circuit means 1 when the synthesizer switch means 1 is set to cause the synthesizer circuit means 1 to select the throttle sound effect desired.

Other circuit control means that are needed to interconnect the component parts of this invention and its novelty effects apparatus are not further described in this specification or illustrated in the drawing, nor is any electric schematic provided, as this provision is thought to be unnecessary and readily available to the practitioner of the pertinent art. Associated power source such as a battery not shown can be used economically as a power source in the present invention. Other equally equivalent embodiments of the present invention are readily apparent and are intended to be included in the detailed description made herein. Minor modifications, changes in dimensions or materials or sizes and configurations of component parts, and means of attachment to the bicycle 12 or its frame 12D are intended to be included herein. The entirety of the special novelty effects apparatus described and set forth in this specification as the present invention can be provided to the consumer by kit form.

What is claimed is:

1. A special novelty effects apparatus for a wheeled device such as a bicycle, comprising in combination,
synthesizer circuit means including microprocessor circuit means and memory circuit means for providing predetermined programs for different sound effects for simulation of selected sounds atypical to the wheeled device on which the synthesizer circuit means is mounted;
synthesizer switch means including multiple switch settings, each one of the switch settings responsive to select from the synthesizer circuit means a different predetermined program of sound effects;
tailpipe cover plate means including tailpipe speaker device responsive to a selected one of the synthesizer circuit means predetermined programs to provide predetermined sound effect atypical to the sound of the wheeled device on which mounted; and
potentiometer throttle means pivotable to a predetermined throttle position to activate a corresponding throttle sound effect provided by the synthesizer circuit means when the synthesizer switch means is set to cause the synthesizer circuit means to select the throttle sound effect desired.

2. The special novelty effects apparatus of claim 1 wherein there is provided tailpipe lighting device responsive to a selected one of the synthesizer circuit means predetermined programs to provide predetermined lighting effect additive to and corresponding with the sound effects emitted by the tailpipe speaker device.

3. The special novelty effects apparatus of claim 1 wherein there is provided a front speaker device responsive to a selected one of the synthesizer circuit means predetermined programs to provide predetermined sound effect atypical to the sounds of the wheeled device on which mounted.

4. The special novelty effects apparatus of claim 1 wherein there is provided a front lighting device responsive to a selected one of the synthesizer circuit means predetermined programs to provide predetermined lighting effect atypical to the sounds of the wheeled device on which mounted.

5. The special novelty effects apparatus of claim 1 wherein there is provided a generator sensor device responsive to movement of sensor means provided thereon to provide generated power to the synthesizer circuit means.

6. The special novelty effects apparatus of claim 4 wherein there is provided front lighting switch means for the front lighting device to turn the front lighting device to an on position, and the tailpipe lighting device is responsive to be turned to an on position so long as the front lighting switch turns the front lighting device to the on position.

7. A special novelty effects apparatus for a wheeled device such as a bicycle, comprising in combination,
synthesizer circuit means including microprocessor circuit means and memory circuit means for providing predetermined programs for different sound effects for simulation of selected sounds atypical to the wheeled device on which the synthesizer circuit means is mounted;
synthesizer switch means including multiple switch settings, each one of the switch settings responsive to select from the synthesizer circuit means a different predetermined program of sound effects;
tailpipe cover plate means including tailpipe speaker device responsive to a selected one of the synthesizer circuit means predetermined programs to provide predetermined sound effect atypical to the sound of the wheeled device on which mounted; and tailpipe lighting device responsive to a selected one of the synthesizer circuit means predetermined programs to provide predetermined lighting effect corresponding to the sound effects emitted by the tailpipe speaker device;
potentiometer throttle means pivotable to a predetermined throttle position to activate a corresponding throttle sound effect provided by the synthesizer circuit means when the synthesizer switch means is set to cause the synthesizer circuit means to select the throttle sound effect desired.

8. The special novelty effects apparatus of claim 7 wherein there is provided a front speaker device responsive to a selected one of the synthesizer circuit means predetermined programs to provide predetermined sound effect atypical to the sounds of the wheeled device on which mounted.

9. The special novelty effects apparatus of claim 7 wherein there is provided a front lighting device responsive to a selected one of the synthesizer circuit means predetermined programs to provide predetermined lighting effect atypical to the sounds of the wheeled device on which mounted.

10. The special novelty effects apparatus of claim 7 wherein there is provided a generator sensor device responsive to movement of sensor means provided thereon to provide generated power to the synthesizer circuit means.
